(19) United States
(12) Patent Application Publication
(10) Pub. No.: US 2012/0153986 A1
(43) Pub. Date: Jun. 21, 2012

(54) SEMICONDUCTOR DEVICE AND METHOD FOR OPERATING THE SAME

(76) Inventor: Jong-Hwan KIM, Gyeonggi-do (KR)

(21) Appl. No.: 13/221,073

(22) Filed: Aug. 30, 2011

(30) Foreign Application Priority Data
Dec. 17, 2010 (KR) 10-2010-0129758

(51) Int. Cl. H03K 19/00; G05F 3/02

(52) U.S. Cl. 326/16; 327/536

(57) ABSTRACT

A semiconductor device includes a pump voltage detecting unit, an oscillation signal generating unit, and a pump voltage generating unit. The pump voltage detecting unit is configured to detect the level of a pump voltage based on a target level varying in response to a test signal. The oscillation signal generating unit is configured to generate an oscillation signal in response to an output signal of the pump voltage detecting unit, wherein the frequency of the oscillation signal varies in response to the test signal. The pump voltage generating unit is configured to generate the pump voltage by performing a charge pumping operation at a speed corresponding to the frequency of the oscillation signal.

### CROSS-REFERENCE TO RELATED APPLICATIONS

The present application claims priority of Korean Patent Application No. 10-2010-0129758, filed on Dec. 17, 2010, which is incorporated herein by reference in its entirety.

### BACKGROUND

1. Field

Exemplary embodiments of the present invention relate to semiconductor design technology, and more particularly, to a pump voltage generating circuit of a semiconductor device that performs a burn-in test operation.

2. Description of the Related Art

Most semiconductor devices, including a dynamic random access memory (DRAM), generate an internal voltage having a different level than an external power supply voltage (e.g., VDD and VSS) and use it with the external power supply voltage. In general, an internal voltage is generated by a charge pumping method or a voltage down-converting method using an external power supply voltage VDD, an external ground voltage VSS and a reference voltage for a target level thereof.

DRAM devices use a charge pumping method to generate internal voltages such as a boost voltage VPP and a back-bias voltage VBB. Also, the DRAM devices use a voltage down-converting method to generate internal voltages such as a core voltage VCORE and a bit line precharge voltage VBLP.

The boost voltage VPP has a higher voltage level than the external power supply voltage VDD and is mostly used to drive word lines. The back-bias voltage VBB is a negative voltage lower than the ground voltage VSS and is mostly used as a body (bulk) bias of a cell transistor (NMOS transistor).

FIG. 1 is a block diagram of a conventional back-bias voltage generating circuit of a semiconductor device. FIG. 2 is a graph illustrating the features of the back-bias voltage generating circuit illustrated in FIG. 1.

Referring to FIG. 1, a conventional back-bias voltage generating circuit includes: a back-bias voltage detecting unit 100 configured to detect the level of a back-bias voltage VBB on the basis of the predetermined level of a back-bias reference voltage VREFB to generate a level detection signal OSCEN; an oscillation signal generating unit 120 configured to generate an oscillation signal OSC of a predetermined frequency in response to the level detection signal OSCEN; and a back-bias voltage generating unit 140 configured to generate the back-bias voltage VBB by performing a charge pumping operation in response to the oscillation signal OSC.

The back-bias voltage detecting unit 100 includes a division voltage generating unit 102 configured to generate a division voltage DET by dividing the level of the back-bias voltage VBB; and a voltage level detecting unit 104 configured to determine the logic level of the level detection signal OSCEN by comparing the level of the division voltage DET with the level of the back-bias reference voltage VREFB.

When the level of the division voltage DET obtained by dividing the level of the back-bias voltage VBB is lower than the level of the back-bias reference voltage VREFB (i.e., when a negative level of the back-bias voltage VBB is higher than a predetermined target level in an absolute value/magnitude), the level detection signal OSCEN is deactivated to prevent the oscillation of the oscillation signal OSC. Accordingly, the back-bias voltage generating unit 140 does not perform a charge pumping operation, so that an operation of generating the back-bias voltage VBB is stopped. That is, when the level of the division voltage DET obtained by dividing the level of the back-bias voltage VBB is lower than the level of the back-bias reference voltage VREFB, the level of the back-bias voltage VBB is controlled not to be decreased further because it already has a sufficiently low level.

On the other hand, when the level of the division voltage DET obtained by dividing the level of the back-bias voltage VBB is higher than the level of the back-bias reference voltage VREFB (i.e., when the negative level of the back-bias voltage VBB is lower than a predetermined target level in an absolute value), the level detection signal OSCEN is activated to enable the oscillation signal OSC to oscillate. Accordingly, the back-bias voltage generating unit 140 performs a charge pumping operation to generate the back-bias voltage VBB. That is, when the level of the division voltage DET obtained by dividing the level of the back-bias voltage VBB is higher than the level of the back-bias reference voltage VREFB, the level of the back-bias voltage VBB is controlled to be decreased because it does not have a sufficiently low level.

Although not illustrated in the drawings, the configuration of a circuit for generating a boost voltage VPP through a charge pumping operation is very similar to the configuration of the back-bias voltage generating circuit illustrated in FIG. 1. That is, like the back-bias voltage generating circuit, a boost voltage generating circuit may include an element configured to detect the level of a boost voltage VPP, an element configured to generate an oscillation signal in response to the detection result, and an element configured to generate the boost voltage VPP through a charge pumping operation in response to eh oscillation signal.

In the process of fabricating semiconductor devices, various test operations are performed to determine whether the semiconductor devices can perform proper operations. Also, various stress test operations are performed to expose the semiconductor devices to more severe environments than the actual environments that the semiconductor devices are used in order to detect the limits of the semiconductor devices. For example, a burn-in test operation which is one of the stress test operations for the semiconductor device such as DRAM may activate a plurality of word lines or all word lines simultaneously during a test operation even while supplying the power supply voltage VDD of a higher level.

When a word line is activated, a leakage current (Gate Induced Drain Lowering (GIDL)) may flow from a boost voltage (VPP) terminal connected to the gate of a cell transistor to a back-bias voltage (VBB) terminal connected to the body (bulk) of a cell transistor (NMOS transistor).

The leakage current GIDL increases in proportion to the number of activated word lines. When all the word lines are activated, a back-bias voltage pump may not be adequate to drive the back-bias voltage VBB the back-bias voltage VBB to be higher than a target level as illustrated in FIG. 2. When the back-bias voltage VBB is generated to be higher than the target level, the threshold voltage level of the cell transistor drops, so that the boost voltage VPP may be lower than a target level as illustrated in the graph of FIG. 2.

If the boost voltage VPP applied to the gate of the cell transistor and the back-bias voltage VBB applied as the body (bulk) bias of the cell transistor (NMOS transistor) fail to have the respective target levels, the cell transistor cannot operate properly and a burn-in test operation may not be properly performed to test other operations of the semiconductor device.

### SUMMARY

An embodiment of the present invention is directed to a semiconductor device that can generate a pump voltage stably even in a test operation such as a burn-in test operation in which the semiconductor device is exposed to high-stress environments.

In accordance with an embodiment of the present invention, a semiconductor device includes: a pump voltage detecting unit configured to detect a level of a pump voltage based on a target level varying in response to a test signal; an oscillation signal generating unit configured to generate an oscillation signal in response to an output signal of the pump voltage detecting unit, wherein a frequency of the oscillation signal varies in response to the test signal; and a pump voltage generating unit configured to generate the pump voltage by performing a charge pumping operation at a speed corresponding to the frequency of the oscillation signal.

In accordance with another embodiment of the present invention, a method for operating a semiconductor device includes: detecting a level of a pump voltage based on a first target level and generating the pump voltage with a first driving force in response to a detection result in a normal operation; and detecting the level of the pump voltage based on a second target level and generating the pump voltage with a second driving force higher than the first driving force in response to a detection result in a test operation mode.

In accordance with another embodiment of the present invention, a semiconductor device including a pump voltage detecting unit configured to detect a level of a pump voltage based on a target level varying in response to a test signal; a normal oscillation signal generating unit configured to generate a normal oscillation signal of a first frequency in response to the test signal and an output signal of the pump voltage detecting unit; a test oscillation signal generating unit configured to generate a test oscillation signal of a second frequency higher than the first frequency in response to the test signal and the output signal of the pump voltage detecting unit; an oscillation output unit configured to output one of the test oscillation signal and the normal oscillation signal as an oscillation signal in response to the test signal; and a pump voltage generating unit configured to generate the pump voltage by performing a charge pumping operation at a speed corresponding to the frequency of the oscillation signal

### BRIEF DESCRIPTION OF THE DRAWINGS

FIG. 1 is a block diagram of a conventional back-bias voltage generating circuit of a semiconductor device.

FIG. 2 is a graph illustrating the features of the back-bias voltage generating circuit illustrated in FIG. 1.

FIG. 3 is a block diagram of a pump voltage generating circuit of a semiconductor device in accordance with an exemplary embodiment of the present invention.

FIGS. 4A and 4B are schematic circuit diagrams of a voltage detecting unit and an oscillation signal generating unit shown in FIG. 3 for a back-bias voltage generating circuit.

FIGS. 5A and 5B are schematic circuit diagrams of the voltage detecting unit and an oscillation signal generating unit shown in FIG. 3 for a boost voltage generating circuit.

FIG. 6 is a schematic circuit diagram of a test signal generating unit shown in FIG. 3.

FIG. 7 is a block diagram of a pump voltage generating circuit of a semiconductor device in accordance with another exemplary embodiment of the present invention.

FIG. 8 is a schematic circuit diagram of a normal oscillation signal generating unit and a test oscillation signal generating unit shown in FIG. 7.

FIG. 9 is a schematic circuit diagram of a pass unit shown in FIG. 7.

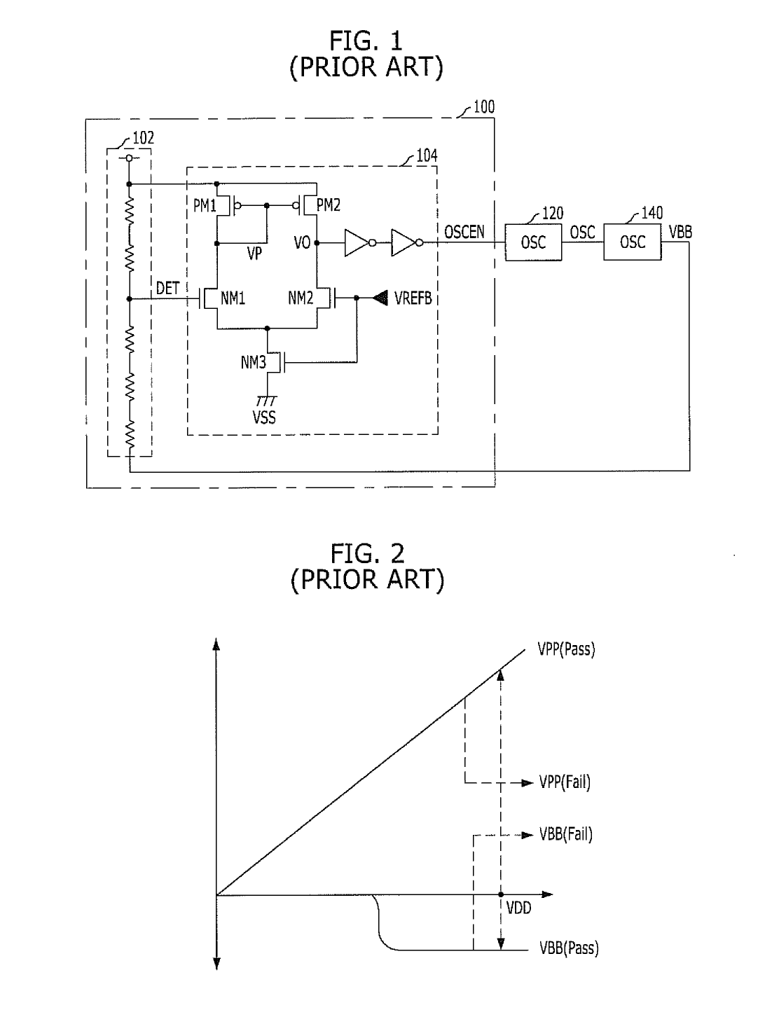

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

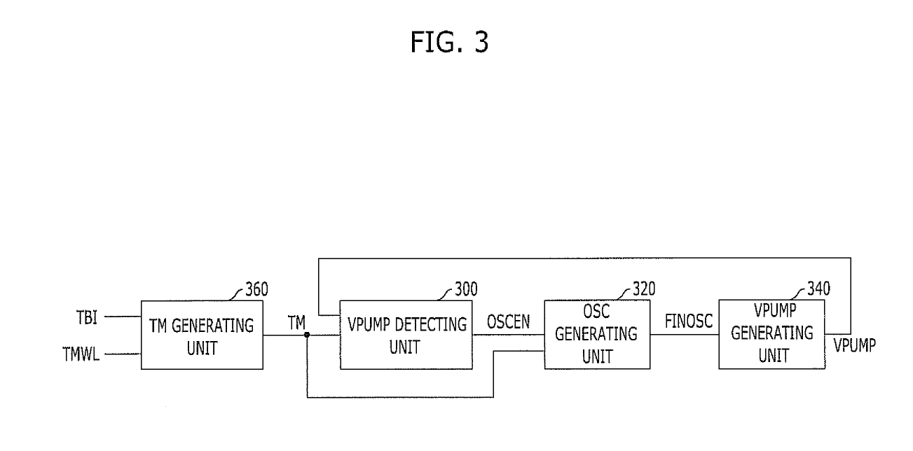

FIG. 3 is a block diagram of a pump voltage generating circuit of a semiconductor device in accordance with an exemplary embodiment of the present invention.

Referring to FIG. 3, a pump voltage generating circuit of a semiconductor device in accordance with an exemplary embodiment of the present invention includes: a voltage detecting unit 300 configured to detect the level of a pump voltage VPUMP on the basis of a target level varying in response to a test signal TM; an oscillation signal generating unit 320 configured to generate an oscillation signal FINOSC in response to an output signal OSCEN of the voltage detecting unit 300, wherein the frequency of the oscillation signal FINOSC varies in response to the test signal TM; and a pump voltage generating unit 340 configured to generate the pump voltage VPUMP by performing a charge pumping operation at a speed corresponding to the frequency of the oscillation signal FINOSC.

The pump voltage generating circuit further includes a test signal generating unit 360 configured to generate the test signal TM in response to a word line enable signal TMWL and a burn-in signal TBI. The word line enable signal TMWL is enabled whenever every word line is operated. The burn-in signal TBI is used for applying a stress to a cell transistor.

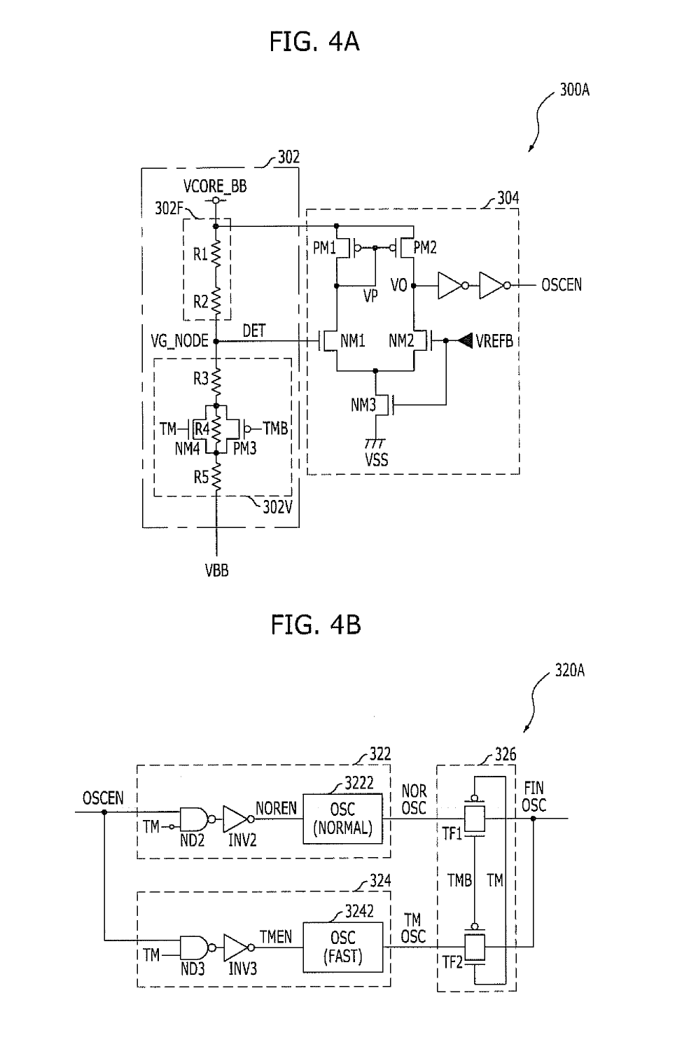

FIGS. 4A and 4B are schematic circuit diagrams of the voltage detecting unit and the oscillation signal generating unit shown in FIG. 3 for a back-bias voltage generating circuit.

Here, the pump voltage detecting unit 300 operates as a back-bias voltage detecting unit 300A; and the oscillation signal generating unit 320 operates as a back-bias oscillation signal generating unit 320A. Thus, the pump voltage VPUMP outputted from the pump voltage generation unit 340 becomes a back-bias voltage VBB.

The back-bias voltage detecting unit 300A includes: a division voltage generating unit 302 configured to generate a division voltage DET by dividing the level of the back-bias voltage VBB at a division ratio varying in response to the test signal TM; and a voltage level detecting unit 304 configured to generate a level detection signal OSCEN by detecting the level of the division voltage DET on the basis of the level of a back-bias reference voltage VREFB.

The division voltage generating unit 302 includes a fixed/constant resistance unit 302F and a variable resistance unit 302V connected in series between a back-bias voltage (VBB) terminal and a back-bias power supply voltage (VCORE_VBB) terminal and generates the division voltage DET at a division voltage generating node VG_NODE to which the fixed resistance unit 302F and the variable resistance unit 302V are connected in common, wherein the fixed resistance unit 302F has a predetermined resistance value and the variable resistance unit 302V has a resistance value varying in response to the test signal TM.

The variable resistance unit 302V includes: a plurality of resistors R3, R4, and R5 connected in series between the division voltage generating node VG_NODE and the back-bias voltage (VBB) terminal; and pass gates NM4 and PM3 connected in parallel between both ends of one of the resistors R3, R4, and R5 and used for current bypass in response to the test signal TM.

The back-bias oscillation signal generating unit 320A includes: a normal oscillation signal generating unit 322 configured to generate a normal oscillation signal NOROSC with a first frequency in response to the test signal TM and the level detection signal OSCEN; a test oscillation signal generating unit 324 configured to generate a test oscillation signal TMOSC with a second frequency higher than the first frequency in response to the test signal TM and the level detection signal OSCEN; and an oscillation output unit 326 configured to output one of the test oscillation signal TMOSC and the normal oscillation signal NOROSC as the oscillation signal FINOSC in response to the test signal TM.

With respect to the above-described configuration shown in FIGS. 4A and 4B, an operation of the back-bias voltage generating circuit in accordance with an exemplary embodiment of the present invention is described as follows.

In a normal operation mode, because the test signal TM is deactivated to a logic low level, the division voltage generating unit 302 does not use the pass gates NM4 and PM3 for current bypass when dividing the level of the back-bias voltage VBB to generate the division voltage DET. Thus, the division voltage generating unit 302 generates the division voltage DET with all the resistors R3, R4, and R5 of the variable resistance unit 302V. That is, in the normal operation mode where the test signal TM is deactivated to a logic low level, the division voltage generating unit 302 generates the division voltage DET by dividing the level of the back-bias voltage VBB with the resistors R1 and R2 included in the fixed resistance unit 302F and the resistors R3, R4, and R5 included in the variable resistance unit 302V.

In a test operation mode, because the test signal TM is activated to a logic high level, the division voltage generating unit 302 uses the pass gates NM4 and PM3 for current bypass when dividing the level of the back-bias voltage VBB to generate the division voltage DET. Thus, the division voltage generating unit 302 generates the division voltage DET with, for example, only the resistors R3 and R5 of the variable resistance unit 302V. That is, in the test operation mode where the test signal TM is activated to a logic high level, the division voltage generating unit 302 generates the division voltage DET by dividing the level of the back-bias voltage VBB with the resistors R1 and R2 included in the fixed resistance unit 302F and the resistors R3 and R5 included in the variable resistance unit 302V.

In this manner, the logic level variation criterion of the division voltage DET generated by the division voltage generating unit 302 may vary in response to the logic level of the test signal TM.

Specifically, if all of the resistors R1, R2, R3, R4, and R5 included in the division voltage generating unit 302 have the same resistance value, the resistance value of the variable resistance unit 302V is greater than the resistance value of the fixed resistance unit 302F in the period when the test signal TM is deactivated to a logic low level. Thus, in the period when the test signal TM is deactivated to a logic low level, the division voltage generating unit 302 generates the division voltage DET that has a voltage level higher than the level of the back-bias voltage VBB by 3 levels each obtained by dividing level difference between the back-bias voltage VBB and the back-bias power supply voltage VCORE_VBB into five equal levels. For example, if the level of the back-bias power supply voltage VCORE_VBB is 1.2V, when the level of the back-bias voltage VBB is −0.8V, the level of the division voltage DET is 0.4V.

On the other hand, if all of the resistors R1, R2, R3, R4, and R5 included in the division voltage generating unit 302 have the same resistance value, the fixed resistance unit 302F and the variable resistance unit 302V have the same resistance value in the period when the test signal TM is activated to a logic high level. Thus, in the period when the test signal TM is activated to a logic high level, the division voltage generating unit 302 generates the division voltage DET that has a voltage level corresponding to the middle level between the level of the back-bias voltage VBB and the level of the back-bias power supply voltage VCORE_VBB. For example, if the level of the back-bias power supply voltage VCORE_VBB is 1.2V, when the level of the back-bias voltage VBB is −0.8V, the level of the division voltage DET is 0.2V.

As described above, it can be seen that the level of the division voltage DET may vary greatly in response to the level of the test signal TM when the level of the back-bias power supply voltage VCORE_VBB and the level of the back-bias voltage VBB are fixed to predetermined levels.

The voltage level detecting unit 304 determines the logic level of the level detection signal OSCEN by comparing the level of the division voltage DET outputted from the division voltage generating unit 302 and the predetermined level of a back-bias reference voltage VREFB.

Specifically, the level detection signal OSCEN is deactivated when the level of the division voltage DET is lower than the level of the back-bias reference voltage VREFB (i.e., when the negative level of the back-bias voltage VBB is higher than a predetermined target level in an absolute value). On the other hand, the level detection signal OSCEN is activated when the level of the division voltage DET is higher than the level of the back-bias reference voltage VREFB (i.e., when the negative level of the back-bias voltage VBB is lower than a predetermined target level in an absolute value).

Because the level of the division voltage DET outputted from the division voltage generating unit 302 may vary according to the test signal TM, the criterion of determining the logic level of the level detection signal OSCEN in the voltage level detecting unit 304 may also vary according to the test signal TM.

For example, if the level of the back-bias reference voltage VREFB is 0.4V, the logic level of the level detection signal OSCEN is determined on whether the division voltage DET is greater than 0.4V. Here, if the level of the back-bias power supply voltage VCORE_VBB is 1.2V in the normal operation mode where the test signal TM is deactivated to a logic low level, when the level of the back-bias voltage VBB is −0.8V, the level of the division voltage DET becomes 0.4V. However, if the level of the back-bias power supply voltage VCORE_VBB is 1.2V in the test operation mode where the test signal TM is activated to a logic high level, when the level of the back-bias voltage VBB is −0.4V, the level of the division voltage DET becomes 0.4V.

That is, in combination with the operation of the voltage level detecting unit 304 for determining the logic level of the level detection signal OSCEN by comparing the predetermined voltage level of the back-bias reference voltage VREFB and the level of the division voltage DET, the operation of the division voltage generating unit 302 for varying the level of the division voltage DET according to the test signal TM may greatly vary the target level of the back-bias voltage VBB.

Consequently, the back-bias voltage detecting unit 300 according to the present invention determines the logic level of the level detection signal OSCEN by detecting the back-bias voltage VBB on the basis of the target level of the back-bias voltage VBB which varies in response to the test signal TM. For example, in the normal operation mode where the test signal TM is deactivated to a logic low level, the logic level of the level detection signal OSCEN is determined on the basis of the voltage level ‘−0.8V’ of the back-bias voltage VBB. On the other hand, in the test operation mode where the test signal TM is activated to a logic high level, the logic level of the level detection signal OSCEN is determined on the basis of the voltage level ‘−0.4V’ of the back-bias voltage VBB.

The back-bias oscillation signal generating unit 320A operates to vary the frequency of the oscillation signal FINOSC, which is generated in response to the level detection signal OSCEN outputted from the back-bias voltage detecting unit 300, according to the test signal TM.

Specifically, when the test signal TM is deactivated to a logic low level, the normal oscillation signal generating unit 322 of the back-bias oscillation signal generating unit 320A outputs the level detection signal OSCEN as a normal detection signal NOREN. However, when the test signal TM is activated to a logic high level, the normal detection signal NOREN is maintained in the deactivated state regardless of the logic level of the level detection signal OSCEN. Thus, it can be seen that a normal oscillation signal outputting unit 3222 outputting a normal oscillation signal NOROSC with a first frequency in response to the normal detection signal NOREN in the normal oscillation signal generating unit 322 operates only in the period when the test signal TM is deactivated to a logic low level. That is, in the period when the test signal TM is deactivated to a logic low level, the normal oscillation signal generating unit 322 generates a normal oscillation signal NOROSC with a first frequency when the level detection signal OSCEN is activated to a logic high level. That is, the normal oscillation signal NOROSC does not oscillate when the level detection signal OSCEN is deactivated to a logic low level. On the other hand, in the period when the test signal TM is activated to a logic high level, the normal oscillation signal generating unit 322 deactivates the normal oscillation signal NOROSC regardless of the logic level of the level detection signal OSCEN.

Meanwhile, when the test signal TM is activated to a logic high level, the test oscillation signal generating unit 324 of the back-bias oscillation signal generating unit 320A outputs the level detection signal OSCEN as a test detection signal TMEN. However, when the test signal TM is deactivated to a logic low level, the test detection signal TMEN is maintained in the deactivated state regardless of the logic level of the level detection signal OSCEN. Thus, it can be seen that a test oscillation signal outputting unit 3242 outputting a test oscillation signal TMOSC with a second frequency higher than the first frequency in response to the test detection signal TMEN in the test oscillation signal generating unit 324 operates only in the period when the test signal TM is activated to a logic high level. That is, in the period when the test signal TM is activated to a logic high level, the test oscillation signal generating unit 324 generates a test oscillation signal NOROSC with the second frequency when the level detection signal OSCEN is activated to a logic high level. That is, the test oscillation signal TMOSC does not oscillate when the level detection signal OSCEN is deactivated to a logic low level. On the other hand, in the period when the test signal TM is deactivated to a logic low level, the test oscillation signal generating unit 324 deactivates the test oscillation signal TMOSC regardless of the logic level of the level detection signal OSCEN.

In summary, the normal oscillation signal generating unit 322 and the test oscillation signal generating unit 324 may operate in the opposite conditions on the basis of the logic level of the test signal TM, and may generate respective oscillation signals NOROSC and TMOSC with different frequencies.

The oscillation output unit 326 of the back-bias oscillation signal generating unit 320A determines whether to output the normal oscillation signal NOROSC or the test oscillation signal TMOSC as the oscillation signal FINOSC in response to the logic level of the test signal TM.

That is, in the test operation mode where the test signal TM is activated to a logic high level, the test oscillation signal TMOSC is outputted as the oscillation signal FINOSC. However, in the normal operation mode where the test signal TM is deactivated to a logic low level, the normal oscillation signal NOROSC is outputted as the oscillation signal FINOSC. Thus, it can be seen that the oscillation signal FINOSC has a relatively high second frequency in the test operation mode where the test signal TM is activated to a logic high level and has a relatively low first frequency in the normal operation mode where the test signal TM is deactivated to a logic low level.

The pump voltage generating unit 340 performs a charge pumping operation at the speed corresponding to the frequency of the oscillation signal FINOSC to generate the back-bias voltage VBB. Thus, the pump voltage generating unit 340 generates the back-bias voltage VBB with a relatively high driving force in the test operation mode where the oscillation signal FINOSC has a relatively high second frequency. On the other hand, the pump voltage generating unit 340 generates the back-bias voltage VBB with a relatively low driving force in the normal operation mode where the oscillation signal FINOSC has a relatively low first frequency.

As described above, the back-bias voltage generating circuit in accordance with an exemplary embodiment of the present invention varies the target level of the back-bias voltage (VBB), which is the criterion for controlling the on/off of a charge pumping operation, in response to the test signal TM and also varies the driving force of a charge pumping operation in response to the test signal TM.

Specifically, in the normal operation mode where the test signal TM is deactivated to a logic low level, the target level of the back-bias voltage VBB is maintained to be relatively high (in an absolute value), and the driving force of the charge pumping operation is controlled to be relatively low.

That is, in the normal operation mode where the number of simultaneously-activated word lines is small and a leakage current GIDL is relatively small, the stable voltage level of the back-bias voltage VBB can be maintained even when the target level of the back-bias voltage VBB has a more negative value and the driving force of the charge pumping operation is controlled to be relatively low. On the other hand, in the test operation mode where the test signal TM is activated to a logic high level, the target level of the back-bias voltage VBB is maintained to be relatively low (in an absolute value), and the driving force of the charge pumping operation is controlled to be relatively high.

That is, in the test operation mode where the number of simultaneously-activated word lines is very large and a leakage current GIDL is relatively very large, the stable voltage level of the back-bias voltage VBB can be maintained only when the target level of the back-bias voltage VBB has a less negative value and the driving force of the charge pumping operation is controlled to be relatively high.

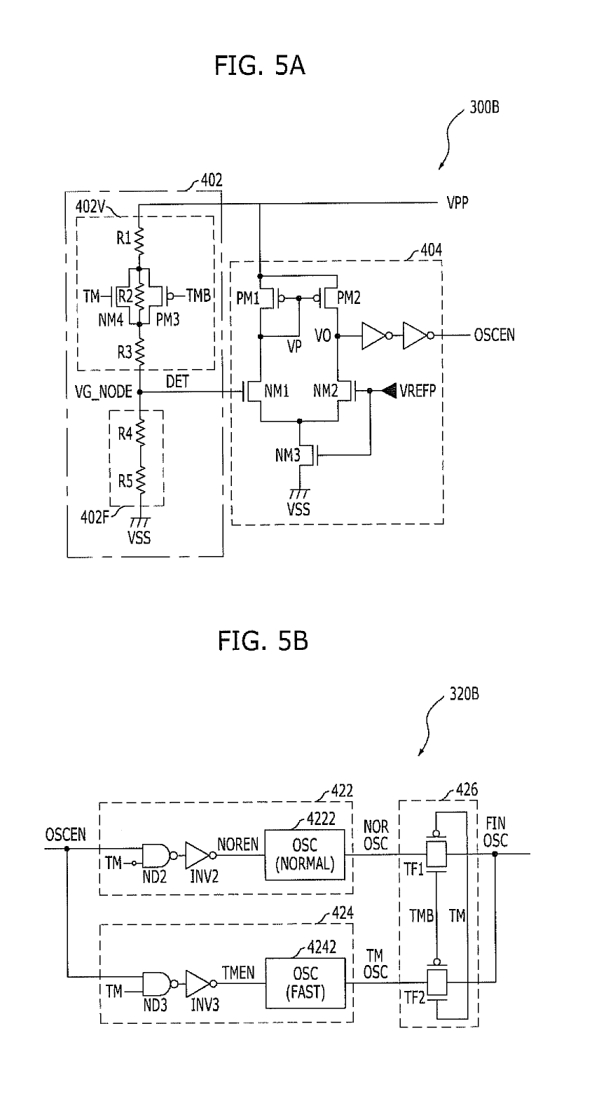

FIGS. 5A and 5B are schematic circuit diagrams of the voltage detecting unit 300 and the oscillation signal generating unit 320 shown in FIG. 3 for a boost voltage generating circuit.

Here, the pump voltage detecting unit 300 operates as a boost voltage detecting unit 300B; and the oscillation signal generating unit 320 operates as a boost oscillation signal generating unit 320B. Thus, the pump voltage VPUMP outputted from the pump voltage generation unit 340 becomes a boost voltage VPP

The boost voltage detecting unit 300B is configured to detect the level of a boost voltage VPP on the basis of a target level varying in response to a test signal TM.

The boost voltage detecting unit 300B includes: a division voltage generating unit 402 configured to generate a division voltage DET by dividing the level of the boost voltage VPP at a division ratio varying in response to the test signal TM; and a voltage level detecting unit 404 configured to generate a level detection signal OSCEN by detecting the level of the division voltage DET on the basis of the level of a boost reference voltage VREFP.

The division voltage generating unit 402 includes a fixed resistance unit 402F and a variable resistance unit 402V connected in series between a boost voltage (VPP) terminal and a ground voltage (VSS) terminal and generates the division voltage DET at a division voltage generating node VG_NODE to which the fixed resistance unit 402F and the variable resistance unit 402V are connected in common, wherein the fixed resistance unit 402F has a predetermined resistance value and the variable resistance unit 402V has a resistance value varying in response to the test signal TM.

The variable resistance unit 402V includes: a plurality of resistors R1, R2, and R3 connected in series between the boost voltage (VPP) terminal and the division voltage generating node VG_NODE; and pass gates NM4 and PM3 connected in parallel between both ends of one of the resistors R1, R2, and R3 and used for current bypass in response to the test signal TM.

The boost oscillation signal generating unit 320B is configured to generate an oscillation signal FINOSC in response to an output signal OSCEN of the boost voltage detecting unit 300B, wherein the frequency of the oscillation signal FINOSC varies in response to the test signal TM.

The boost oscillation signal generating unit 320B includes: a normal oscillation signal generating unit 422 configured to generate a normal oscillation signal NOROSC with a first frequency in response to the test signal TM and the level detection signal OSCEN; a test oscillation signal generating unit 424 configured to generate a test oscillation signal TMOSC with a second frequency higher than the first frequency in response to the test signal TM and the level detection signal OSCEN; and an oscillation output unit 426 configured to output one of the test oscillation signal TMOSC and the normal oscillation signal NOROSC as the oscillation signal FINOSC in response to the test signal TM.

With respect to the above-described configuration, an operation of the boost voltage generating circuit in accordance with an exemplary embodiment of the present invention will be described below in detail.

In a normal operation mode, because the test signal TM is deactivated to a logic low level, the division voltage generating unit 402 does not use the pass gates NM4 and PM3 for current bypass when dividing the level of the boost voltage VPP to generate the division voltage DET. Thus, the division voltage generating unit 402 generates the division voltage DET with all the resistors R1, R2, and R3 of the variable resistance unit 402V. That is, in the normal operation mode where the test signal TM is deactivated to a logic low level, the division voltage generating unit 402 generates the division voltage DET by dividing the level of the boost voltage VPP with the resistors R4 and R5 included in the fixed resistance unit 402F and the resistors R1, R2, and R3 included in the variable resistance unit 402V.

In a test operation mode, because the test signal TM is activated to a logic high level, the division voltage generating unit 402 uses the pass gates NM4 and PM3 for current bypass when dividing the level of the boost voltage VPP to generate the division voltage DET. Thus, the division voltage generating unit 402 generates the division voltage DET with only the resistors R1 and R3 of the variable resistance unit 402V. That is, in the test operation mode where the test signal TM is activated to a logic high level, the division voltage generating unit 402 generates the division voltage DET by dividing the level of the boost voltage VPP with the resistors R4 and R5 included in the fixed resistance unit 402F and the resistors R1 and R3 included in the variable resistance unit 402V.

In this manner, the logic level variation criterion of the division voltage DET generated by the division voltage generating unit 402 may vary in response to the logic level of the test signal TM.

Specifically, if all of the resistors R1, R2, R3, R4, and R5 included in the division voltage generating unit 402 have the same resistance value, the resistance value of the variable resistance unit 402V is greater than the resistance value of the fixed resistance unit 402F in the period when the test signal TM is deactivated to a logic low level. Thus, in the period when the test signal TM is deactivated to a logic low level, the division voltage generating unit 402 generates the division voltage DET that has a voltage level lower than the level of the boost voltage VPP by 3 levels each obtained by dividing a voltage level difference between the boost voltage VPP and the ground voltage VSS into five equally spaced voltage levels. For example, if the level of the boost voltage VPP is 3V, the level of the division voltage DET is 1.2V.

On the other hand, if all of the resistors R1, R2, R3, R4, and R5 included in the division voltage generating unit 402 have the same resistance value, the fixed resistance unit 402F and the variable resistance unit 402V have the same resistance value in the period when the test signal TM is activated to a logic high level. Thus, in the period when the test signal TM is activated to a logic high level, the division voltage generating unit 402 generates the division voltage DET that has a voltage level located at the middle point between the level of the boost voltage VPP and the level of the ground voltage VSS. For example, if the level of the boost voltage VPP is 3V, the level of the division voltage DET is 1.5V.

As described above, it can be seen that the level of the division voltage DET may vary greatly in response to the level of the test signal TM when the level of the boost voltage VPP is fixed to a predetermined level.

The voltage level detecting unit 404 determines the logic level of the level detection signal OSCEN by comparing the level of the division voltage DET outputted from the division voltage generating unit 402 and the predetermined level of a back-bias reference voltage VREFB.

Specifically, the level detection signal OSCEN is deactivated when the level of the division voltage DET is higher than the level of the boost reference voltage VREFP. On the other hand, the level detection signal OSCEN is activated when the level of the division voltage DET is lower than the level of the boost reference voltage VREFP.

Because the level of the division voltage DET outputted from the division voltage generating unit 402 may vary according to the test signal TM, the criterion of determining the logic level of the level detection signal OSCEN in the voltage level detecting unit 404 may also vary according to the test signal TM.

For example, if the level of the boost reference voltage VREFP is 1.2V, the logic level of the level detection signal OSCEN is determined on whether the division voltage DET is greater than 1.2V. Here, in the normal operation mode where the test signal TM is deactivated to a logic low level, when the level of the boost voltage VPP is 3V, the level of the division voltage DET becomes 1.2V. However, in the test operation mode where the test signal TM is activated to a logic high level, when the level of the boost voltage VPP is 2.4V, the level of the division voltage DET becomes 1.2V.

That is, in combination with the operation of the voltage level detecting unit 404 for determining the logic level of the level detection signal OSCEN by comparing the predetermined voltage level of the boost reference voltage VREFP and the level of the division voltage DET, the operation of the division voltage generating unit 402 for varying the level of the division voltage DET according to the test signal TM may greatly vary the target level of the boost voltage VPP.

Consequently, the boost voltage detecting unit 300B according to the present invention determines the logic level of the level detection signal OSCEN by detecting the boost voltage VPP on the basis of the target level of the boost voltage VPP which varies in response to the test signal TM. For example, in the normal operation mode where the test signal TM is deactivated to a logic low level, the logic level of the level detection signal OSCEN is determined on the basis of the voltage level ‘3V’ of the boost voltage VPP. On the other hand, in the test operation mode where the test signal TM is activated to a logic high level, the logic level of the level detection signal OSCEN is determined on the basis of the voltage level ‘2.4V’ of the boost voltage VPP.

The boost oscillation signal generating unit 320B operates to vary the frequency of the oscillation signal FINOSC, which is generated in response to the level detection signal OSCEN outputted from the boost voltage detecting unit 300B, according to the test signal TM.

Specifically, when the test signal TM is deactivated to a logic low level, the normal oscillation signal generating unit 422 of the boost oscillation signal generating unit 320B outputs the level detection signal OSCEN as a normal detection signal NOREN. However, when the test signal TM is activated to a logic high level, the normal detection signal NOREN is maintained in the deactivated state regardless of the logic level of the level detection signal OSCEN. Thus, it can be seen that a normal oscillation signal outputting unit 4222 outputting a normal oscillation signal NOROSC with a first frequency in response to the normal detection signal NOREN in the normal oscillation signal generating unit 422 operates only in the period when the test signal TM is deactivated to a logic low level. That is, in the period when the test signal TM is deactivated to a logic low level, the normal oscillation signal generating unit 422 generates a normal oscillation signal NOROSC with a first frequency when the level detection signal OSCEN is activated to a logic high level. That is, the normal oscillation signal NOROSC does not oscillate when the level detection signal OSCEN is deactivated to a logic low level. On the other hand, in the period when the test signal TM is activated to a logic high level, the normal oscillation signal generating unit 422 deactivates the normal oscillation signal NOROSC regardless of the logic level of the level detection signal OSCEN.

Meanwhile, when the test signal TM is activated to a logic high level, the test oscillation signal generating unit 424 of the boost oscillation signal generating unit 320B outputs the level detection signal OSCEN as a test detection signal TMEN. However, when the test signal TM is deactivated to a logic low level, the test detection signal TMEN is maintained in the deactivated state regardless of the logic level of the level detection signal OSCEN. Thus, it can be seen that a test oscillation signal outputting unit 4242 outputting a test oscillation signal TMOSC with a second frequency higher than the first frequency in response to the test detection signal TMEN in the test oscillation signal generating unit 424 operates only in the period when the test signal TM is activated to a logic high level. That is, in the period when the test signal TM is activated to a logic high level, the test oscillation signal generating unit 424 generates a test oscillation signal NOROSC with the second frequency when the level detection signal OSCEN is activated to a logic high level. That is, the test oscillation signal TMOSC does not oscillate when the level detection signal OSCEN is deactivated to a logic low level. On the other hand, in the period when the test signal TM is deactivated to a logic low level, the test oscillation signal generating unit 424 deactivates the test oscillation signal TMOSC regardless of the logic level of the level detection signal OSCEN.

In summary, the normal oscillation signal generating unit 422 and the test oscillation signal generating unit 424 may operate in the opposite conditions on the basis of the logic level of the test signal TM, and may generate respective oscillation signals NOROSC and TMOSC with different frequencies.

The oscillation output unit 426 of the boost oscillation signal generating unit 320B determines whether to output the normal oscillation signal NOROSC or the test oscillation signal TMOSC as the oscillation signal FINOSC in response to the logic level of the test signal TM.

That is, in the test operation mode where the test signal TM is activated to a logic high level, the test oscillation signal TMOSC is outputted as the oscillation signal FINOSC. However, in the normal operation mode where the test signal TM is deactivated to a logic low level, the normal oscillation signal NOROSC is outputted as the oscillation signal FINOSC. Thus, it can be seen that the oscillation signal FINOSC has a relatively high second frequency in the test operation mode where the test signal TM is activated to a logic high level and has a relatively low first frequency in the normal operation mode where the test signal TM is deactivated to a logic low level.

The pump voltage generating unit 340 performs a charge pumping operation at the speed corresponding to the frequency of the oscillation signal FINOSC to generate the boost voltage VPP. Thus, the pump voltage generating unit 340 generates the boost voltage VPP with a relatively high driving force in the test operation mode where the oscillation signal FINOSC has a relatively high second frequency. On the other hand, the pump voltage generating unit 340 generates the boost voltage VPP with a relatively low driving force in the normal operation mode where the oscillation signal FINOSC has a relatively first second frequency.

As described above, the boost voltage generating circuit in accordance with an exemplary embodiment of the present invention varies the target level of the boost voltage (VPP), which is the criterion for controlling the on/off of a charge pumping operation, in response to the test signal TM and also varies the driving force of a charge pumping operation in response to the test signal TM.

Specifically, in the normal operation mode where the test signal TM is deactivated to a logic low level, the target level of the boost voltage VPP is maintained to be relatively high, and the driving force of the charge pumping operation is controlled to be relatively low.

That is, in the normal operation mode where the number of simultaneously-activated word lines is small and there is a low probability that the level of the boost voltage VPP drops suddenly, the stable voltage level of the boost voltage VPP can be maintained even when the target level of the boost voltage VPP has a more positive value and the driving force of the charge pumping operation is controlled to be relatively low.

On the other hand, in the test operation mode where the test signal TM is activated to a logic high level, the target level of the boost voltage VPP is maintained to be relatively low, and the driving force of the charge pumping operation is controlled to be relatively high.

That is, in the test operation mode where the number of simultaneously-activated word lines is very large and there is a high probability that the level of the boost voltage VPP drops suddenly, the stable voltage level of the boost voltage VPP can be maintained only when the target level of the boost voltage VPP has a less positive value and the driving force of the charge pumping operation is controlled to be relatively high.

As described above, in accordance with the embodiments of the present invention, the test mode signal TM is used to control the charge pump driving force and the target level of the pump voltage (including the back-bias voltage VBB, the boost voltage VPP, and all internal voltages generated through a pumping operation). Accordingly, the pump voltage maintaining a stable voltage level through the minimum power consumption can be generated in the normal operation mode using a relatively small amount of pump voltage. Also, the pump voltage maintaining a stable voltage level can be generated in the test operation mode using a relatively large amount of pump voltage.

Thus, the level of the pump voltage can always be maintained around a desired target level in the test operation mode where a large number of word lines are simultaneously activated. Accordingly, the burn-in test operation can be properly performed regardless of the number of simultaneously-activated word lines in the state where a cell transistor is exposed to stress. That is, as compared to the conventional method, the preset invention can implement a burn-in test operation of simultaneously activating more word lines, and thus the time taken to perform a burn-in test operation may be minimized.

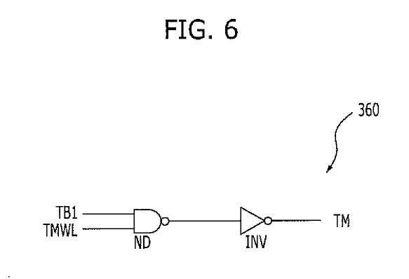

FIG. 6 is a schematic circuit diagram of the test signal generating unit 360 shown in FIG. 3.

The test signal generating unit 360 includes a NAND gate ND and an inverter INV. The NAND gate ND logically combines the word line enable signal TMWL and the burn-in signal TBI; and the inverter INV inverts an output of the NAND gate ND and output the test signal TM.

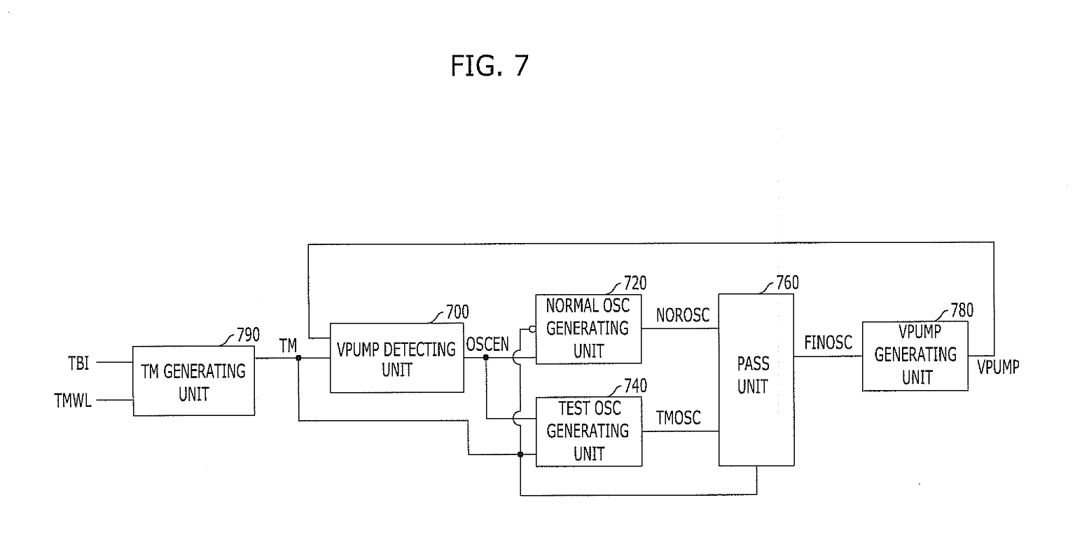

FIG. 7 is a block diagram of a pump voltage generating circuit of a semiconductor device in accordance with another exemplary embodiment of the present invention.

Referring to FIG. 7, a pump voltage generating circuit of a semiconductor device in accordance with an exemplary embodiment of the present invention includes: a voltage detecting unit 700 configured to detect the level of a pump voltage VPUMP on the basis of a target level varying in response to a test signal TM; a normal oscillation signal generating unit 720 configured to generate a normal oscillation signal NOROSC in response to an output signal OSCEN of the voltage detecting unit 700 and the test signal TM; a test oscillation signal generating unit 740 configured to generate a test oscillation signal TMOSC in response to an output signal OSCEN of the voltage detecting unit 700 and the test signal TM; a pass unit 760 configured to generate an oscillation signal FINOSC by selecting one of the normal oscillation signal NOROSC and the test oscillation signal TMOSC; and a pump voltage generating unit 780 configured to generate the pump voltage VPUMP by performing a charge pumping operation at a speed corresponding to the frequency of the oscillation signal FINOSC.

The pump voltage generating circuit further includes a test signal generating unit 790. The voltage detecting unit 700 and the test signal generating unit 790 may respectively have the same structure with the voltage detecting unit 300 and the test signal generating unit 360. That is, the voltage detecting unit 700 may be implemented with the structure shown in FIG. 4A for generating the back-bias voltage VBB and implemented with the structure shown in FIG. 5A for generating the boost voltage VPP. The test signal generating unit 790 may be implanted with the circuit shown in FIG. 6.

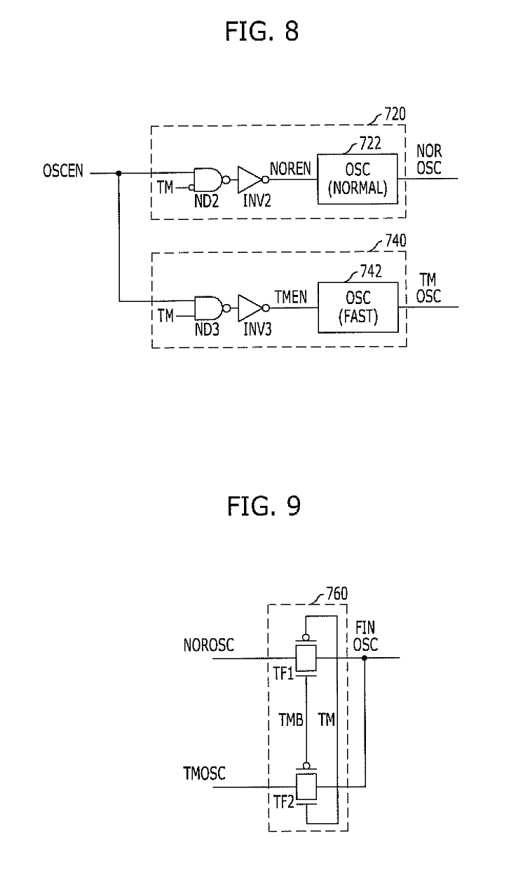

FIG. 8 is a schematic circuit diagram of the normal oscillation signal generating unit 720 and the test oscillation signal generating unit 740 shown in FIG. 7.

When the test signal TM is deactivated to a logic low level, the normal oscillation signal generating unit 720 outputs the level detection signal OSCEN as a normal detection signal NOREN. However, when the test signal TM is activated to a logic high level, the normal detection signal NOREN is maintained in the deactivated state regardless of the logic level of the level detection signal OSCEN. Thus, it can be seen that a normal oscillation signal outputting unit 722 outputting a normal oscillation signal NOROSC with a first frequency in response to the normal detection signal NOREN in the normal oscillation signal generating unit 720 operates only in the period when the test signal TM is deactivated to a logic low level. That is, in the period when the test signal TM is deactivated to a logic low level, the normal oscillation signal generating unit 720 generates a normal oscillation signal NOROSC with a first frequency when the level detection signal OSCEN is activated to a logic high level. That is, the normal oscillation signal NOROSC does not oscillate when the level detection signal OSCEN is deactivated to a logic low level. On the other hand, in the period when the test signal TM is activated to a logic high level, the normal oscillation signal generating unit 720 deactivates the normal oscillation signal NOROSC regardless of the logic level of the level detection signal OSCEN.

Meanwhile, when the test signal TM is activated to a logic high level, the test oscillation signal generating unit 740 outputs the level detection signal OSCEN as a test detection signal TMEN. However, when the test signal TM is deactivated to a logic low level, the test detection signal TMEN is maintained in the deactivated state regardless of the logic level of the level detection signal OSCEN. Thus, it can be seen that a test oscillation signal outputting unit 742 outputting a test oscillation signal TMOSC with a second frequency higher than the first frequency in response to the test detection signal TMEN in the test oscillation signal generating unit 740 operates only in the period when the test signal TM is activated to a logic high level. That is, in the period when the test signal TM is activated to a logic high level, the test oscillation signal generating unit 740 generates a test oscillation signal NOROSC with the second frequency when the level detection signal OSCEN is activated to a logic high level. That is, the test oscillation signal TMOSC does not oscillate when the level detection signal OSCEN is deactivated to a logic low level. On the other hand, in the period when the test signal TM is deactivated to a logic low level, the test oscillation signal generating unit 740 deactivates the test oscillation signal TMOSC regardless of the logic level of the level detection signal OSCEN.

In summary, the normal oscillation signal generating unit 720 and the test oscillation signal generating unit 740 may operate in the opposite conditions on the basis of the logic level of the test signal TM and may generate respective oscillation signals NOROSC and TMOSC with different frequencies.

FIG. 9 is a schematic circuit diagram of the pass unit 760 shown in FIG. 7.

The pas unit 760 determines whether to output the normal oscillation signal NOROSC or the test oscillation signal TMOSC as the oscillation signal FINOSC in response to the logic level of the test signal TM.

That is, in the test operation mode where the test signal TM is activated to a logic high level, the test oscillation signal TMOSC is outputted as the oscillation signal FINOSC. However, in the normal operation mode where the test signal TM is deactivated to a logic low level, the normal oscillation signal NOROSC is outputted as the oscillation signal FINOSC. Thus, it can be seen that the oscillation signal FINOSC has a relatively high second frequency in the test operation mode where the test signal TM is activated to a logic high level and has a relatively low first frequency in the normal operation mode where the test signal TM is deactivated to a logic low level.

The pump voltage generating unit 780 performs a charge pumping operation at the speed corresponding to the frequency of the oscillation signal FINOSC to generate the pump voltage VPUMP. Thus, the pump voltage generating unit 780 generates the pump voltage VPUMP with a relatively high driving force in the test operation mode where the oscillation signal FINOSC has a relatively high second frequency. On the other hand, the pump voltage generating unit 780 generates the pump voltage VPUMP with a relatively low driving force in the normal operation mode where the oscillation signal FINOSC has a relatively low first frequency.

In accordance with the embodiments of the present invention, the positions and types of the logic gates and transistors used herein may be differently implemented depending on polarities of the input signals.

While the present invention has been described with respect to the specific embodiments, it will be apparent to those skilled in the art that various changes and modifications may be made without departing from the spirit and scope of the invention as defined in the following claims.

What is claimed is:

1. A semiconductor device comprising:
a pump voltage detecting unit configured to detect a level of a pump voltage based on a target level varying in response to a test signal;
an oscillation signal generating unit configured to generate an oscillation signal in response to an output signal of the pump voltage detecting unit, wherein a frequency of the oscillation signal varies in response to the test signal; and
a pump voltage generating unit configured to generate the pump voltage by performing a charge pumping operation at a speed corresponding to the frequency of the oscillation signal.

2. The semiconductor device of claim 1, wherein the pump voltage detecting unit includes:
a division voltage generating unit configured to generate a division voltage by dividing the level of the pump voltage at a division ratio varying in response to the test signal; and
a voltage level detecting unit configured to generate a level detection signal by detecting a level of the division voltage based on a level of a pump reference voltage.

3. The semiconductor device of claim 2, wherein the pump voltage is a back-bias voltage.

4. The semiconductor device of claim 3, wherein the division voltage generating unit includes a fixed resistance unit and a variable resistance unit connected in series between a back-bias voltage terminal and a back-bias power supply voltage terminal and generates the division voltage at a division voltage generating node to which the fixed resistance unit and the variable resistance unit are connected in common, wherein the fixed resistance unit has a set resistance value and the variable resistance unit has a resistance value varying in response to the test signal.

5. The semiconductor device of claim 4, wherein the variable resistance unit includes:
a plurality of resistors connected in series between the division voltage generating node and the back-bias voltage terminal; and
pass gates connected in parallel between both ends of at least one of the resistors and used for bypassing current in response to the test signal.

6. The semiconductor device of claim 2, wherein the pump voltage is a boost voltage.

7. The semiconductor device of claim 6, wherein the division voltage generating unit includes a variable resistance unit and a fixed resistance unit connected in series between a boost voltage terminal and a ground voltage terminal and generates the division voltage at a division voltage generating node to which the variable resistance unit and the fixed resistance unit are connected in common, wherein the fixed resistance unit has a constant resistance value and the variable resistance unit has a resistance value varying in response to the test signal.

8. The semiconductor device of claim 7, wherein the variable resistance unit includes:
a plurality of resistors connected in series between the boost voltage unit and the division voltage generating node; and
pass gates connected in parallel between both ends of at least one of the resistors and used for bypassing current in response to the test signal.

9. The semiconductor device of claim 1, wherein the oscillation signal generating unit includes:
a normal oscillation signal generating unit configured to generate a normal oscillation signal with a first frequency in response to the test signal and the output signal of the pump detecting unit;
a test oscillation signal generating unit configured to generate a test oscillation signal with a second frequency higher than the first frequency in response to the test signal and the output signal of the pump detecting unit; and
an oscillation output unit configured to output one of the test oscillation signal and the normal oscillation signal as the oscillation signal in response to the test signal.

10. The semiconductor device of claim 1, wherein the pump voltage generating unit generates the pump voltage by a relatively high driving force in response to a relatively high frequency of the oscillation signal and generates the pump voltage by a relatively low driving force in response to a relatively low frequency of the oscillation signal.

11. The semiconductor device of claim 1, further comprising a test signal generating unit including:
a NAND gate configured to logically combine a burn-in signal for applying stress to a cell transistor and a word line enable signal enabled whenever every word line is operated; and
an inverter configured to generate the test signal by inverting an output of the NAND gate.

12. A method for operating a semiconductor device, comprising:
detecting a level of a pump voltage based on a first target level and generating the pump voltage with a first driving force in response to a detection result in a normal operation; and
detecting the level of the pump voltage based on a second target level and generating the pump voltage with a second driving force higher than the first driving force in response to a detection result in a test operation mode.

13. The method of claim 12, wherein the detecting of the level of the pump voltage and the generating of the pump voltage in the normal operation mode includes:
detecting the level of the pump voltage based on the first target level in a deactivated period of a test signal and determining a value of a detection signal in response to a detection result;
generating an oscillation signal with a first frequency in response to the detection signal in the deactivated period of the test signal; and
performing a charge pumping operation in response to the oscillation signal to generate the pump voltage.

14. The method of claim 13, wherein the detecting of the level of the pump voltage and the generating of the pump voltage in the test operation mode includes:
detecting the level of the pump voltage based on the second target level in an activated period of the test signal and determining the value of the detection signal in response to a detection result;
generating an oscillation signal with a second frequency higher than the first frequency in response to the detection signal in the activated period of the test signal; and
performing a charge pumping operation in response to the oscillation signal to generate the pump voltage.

15. The method of claim 12, wherein the second target level is lower than the first target level.

16. A semiconductor device comprising:
a pump voltage detecting unit configured to detect a level of a pump voltage based on a target level varying in response to a test signal;
a normal oscillation signal generating unit configured to generate a normal oscillation signal of a first frequency in response to the test signal and an output signal of the pump voltage detecting unit;
a test oscillation signal generating unit configured to generate a test oscillation signal of a second frequency higher than the first frequency in response to the test signal and the output signal of the pump voltage detecting unit;
an oscillation output unit configured to output one of the test oscillation signal and the normal oscillation signal as an oscillation signal in response to the test signal; and
a pump voltage generating unit configured to generate the pump voltage by performing a charge pumping operation at a speed corresponding to the frequency of the oscillation signal.

17. The semiconductor device of claim 16, further comprising a test signal generating unit including:
a NAND gate configured to logically combine a burn-in signal for applying stress to a cell transistor and a word line enable signal enabled whenever every word line is operated; and
an inverter configured to generate the test signal by inverting an output of the NAND gate.
